(19) United States
(12) Patent Application Publication
(10) Pub. No.: US 2006/0030103 A1
(43) Pub. Date: Feb. 9, 2006

(54) Semiconductor device and method of manufacturing the same

(76) Inventors: Sung-Un Kwon, Gyeonggi-do (KR); Jae-Seung Hwang, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/187,057

(22) Filed: Jul. 22, 2005

(30) Foreign Application Priority Data
Aug. 3, 2004 (KR) 2004-61073

(51) Int. Cl. H01L 21/336; H01L 21/3205

(52) U.S. Cl. 438/257; 438/593; 438/587; 438/264

(57) ABSTRACT

A semiconductor device includes a substrate having active regions and field regions. A tunnel dielectric layer pattern is formed on the active regions. A first gate pattern is formed on the tunnel dielectric layer pattern to partially expose the tunnel dielectric layer pattern. A dielectric layer pattern is formed on the first gate pattern, the tunnel dielectric layer pattern and the field regions. The dielectric layer pattern includes a first dielectric layer pattern that extends in a first direction and a second dielectric layer pattern that extends in a second direction substantially perpendicular to the first direction. The first dielectric layer pattern is formed on the first gate pattern and the tunnel dielectric layer pattern. The second dielectric layer pattern is formed on the first gate pattern and the field regions. A second gate pattern is formed on the second dielectric layer pattern.

### CROSS REFERENCE TO RELATED APPLICATION

This application claims priority under 35 USC § 119 to Korean Patent Application No. 2004-61073, filed on Aug. 3, 2004, the contents of which are herein incorporated by reference in its entirety.

### BACKGROUND OF THE INVENTION

1. Field of the Invention

The present invention relates to a semiconductor device and a method of manufacturing the same. More particularly, the present invention relates to a flash memory device into/from which data is inputted/outputted while data inputted into the flash memory device are maintained regardless of elapsed time, and a method of manufacturing the flash memory device.

2. Description of the Related Art

Generally, a flash memory device includes a tunnel oxide layer, a floating gate as a first gate pattern, a dielectric layer and a control gate as a second gate pattern sequentially stacked. Examples of the flash memory device are disclosed in U.S. Pat. No. 6,153,469, issued to Yun, et al. and U.S. Pat. No. 6,455,374, issued to Lee, et al.

FIG. 1 is a plan view illustrating a conventional semiconductor device.

Referring to FIG. 1, the conventional semiconductor device corresponds to a flash memory device. The conventional flash memory device includes a semiconductor substrate 10 on which an active region 12 and a field region 13 are defined, and a gate structure formed on the semiconductor substrate 10. The gate structure includes a tunnel oxide layer pattern, a floating gate 18, an intergate dielectric layer and a control gate 20 sequentially stacked on the semiconductor substrate 10.

FIG. 2 is a cross-sectional view taken along line I-I′ in FIG. 1. With reference to FIG. 2, an isolation layer 14 is formed in the semiconductor substrate 10 to define the active region 12 and the field region 13 of the semiconductor substrate 10. The tunnel oxide layer pattern 15 and the floating gate 18 are formed on the active region 12. The intergate dielectric layer 19 is formed on the floating gate 18 and the isolating layer 14. The control gate 20 is formed on the dielectric layer 19.

FIG. 3 is a cross-sectional view taken along line II-II′ in FIG. 1. With reference to FIG. 3, the tunnel oxide layer pattern 15, the floating gate 18, the intergate dielectric layer 19 and the control gate 20 are sequentially formed on the semiconductor substrate 10. It may be seen that the floating gate 18 extends in a direction substantially parallel to a direction in which the control gate 20 extends.

In the above-mentioned conventional flash memory device, when a voltage is applied to the control gate 20, electrons are charged into or released from the floating gate 18 so that various operations of the flash memory device can be performed. Here, the intergate dielectric layer 19 transmits the voltage from the control gate 20 to the floating gate 18. To improve electrical characteristics of the flash memory device, the loss of the voltage transmitted to the floating gate 18 needs to be reduced. That is, a coupling ratio R needs to be improved. The coupling ratio R is represented as the following Equation 1.
R=C_{ONO}/(C_{ONO}+C_{TO}) Equation 1

In Equation 1, C_{ONO} denotes the capacitance of the intergate dielectric layer 19 and C_{TO} denotes the capacitance of the tunnel oxide layer pattern 15.

Also, the capacitance C of the intergate dielectric layer 19 is represented as the following Equation 2.
C=(ε×A)/T Equation 2

In Equation 2, ε denotes the dielectric constant of the intergate dielectric layer 19, A denotes the area of the intergate dielectric layer 19 and T denotes the thickness of the intergate dielectric layer 19.

Thus, the coupling ratio R can be improved by increasing or expanding the area of the dielectric layer 19, and/or by reducing the thickness of the intergate dielectric layer 19.

Examples of expanding an area of an intergate dielectric layer are disclosed in Japan Patent Laid Open Publication Nos. 2002-26151 and 1997-102554. According to the disclosure in Japan Patent Laid Open Publication No. 2002-26151, a floating gate has a T shape. An intergate dielectric layer is formed on the floating gate having the T shape to expand an area of the intergate dielectric layer.

As described above, in the conventional methods, the area of a dielectric layer expands by modifying the structure of the floating gate. However, because there are limitations against expanding the area of the dielectric layer by improving the structure of the floating gate, it has been difficult to obtain a desirable coupling ratio.

Therefore, there is an immediate need for obtaining a semiconductor device having an improved coupling ratio, especially considering the recent trend of miniaturization.

### SUMMARY OF THE INVENTION

The present invention provides a semiconductor device that includes a dielectric layer having an expanded area.

The present invention also provides a method of manufacturing the above-mentioned semiconductor device.

A semiconductor device in accordance with one aspect of the present invention includes a substrate having active regions and field regions that are alternately arranged in a first direction. A tunnel oxide layer pattern is formed in the active regions. A first gate pattern is formed on the tunnel oxide layer pattern to partially expose a surface of the tunnel oxide layer pattern by or through the first gate pattern. A dielectric layer pattern is formed on the first gate pattern, the tunnel oxide layer pattern and the field regions. The dielectric layer pattern includes a first dielectric layer pattern that extends in the first direction, i.e. is “striped”, and a second dielectric layer pattern that extends in a second direction, i.e. is “striped”, that is substantially perpendicular to the first direction to produce an orthogonal arrangement of patterned dielectric “stripes.” The first dielectric layer pattern is formed on the first gate pattern and the tunnel oxide layer pattern. The second dielectric layer pattern is formed on the first gate pattern and the field regions. A second gate pattern is formed on the second dielectric layer pattern.

In a method of manufacturing a semiconductor device in accordance with another aspect of the present invention, active regions and field regions that are alternately arranged, in a first direction are defined on a substrate. A tunnel oxide layer pattern is formed in the active regions. A first gate pattern is formed on the tunnel oxide layer pattern to partially expose a surface of the tunnel oxide layer pattern by or through the first gate pattern. A dielectric layer pattern is formed on the first gate pattern, the tunnel oxide layer pattern and the field regions. The dielectric layer pattern includes a first dielectric layer pattern that extends in the first direction, i.e. is “striped”, and a second dielectric layer pattern that extends in a second direction, i.e. is “striped”, substantially perpendicular to the first direction to produce an orthogonal array of patterned dielectric “stripes.” The first dielectric layer pattern is formed on the first gate pattern and the tunnel oxide layer pattern. The second dielectric layer pattern is formed on the first gate pattern and the field regions. A second gate pattern is formed on the second dielectric layer pattern.

In a method of manufacturing a semiconductor device in accordance with still another aspect of the present invention, isolation layers are formed in trenches of a substrate in a first direction to define active regions and field regions that are alternately arranged. A tunnel oxide layer and a first conductive layer are sequentially formed on the substrate. Portions of the tunnel oxide layer and the first conductive layer on the field regions are removed to form a tunnel oxide layer pattern on the active regions and a first conductive layer pattern on the tunnel oxide layer pattern. The first conductive layer pattern is patterned to form a first gate pattern on the tunnel oxide layer pattern. A dielectric layer is formed on a resultant structure having the first gate pattern. A second conductive layer is then formed on the dielectric layer. The second conductive layer is patterned to form a second gate pattern over the first gate pattern and the field regions. Portions of the dielectric layer exposed by or through the second gate pattern are patterned to form a dielectric layer pattern. The dielectric layer pattern includes a first dielectric layer pattern on the first gate pattern and the tunnel oxide layer pattern, and a second dielectric layer pattern beneath the second gate pattern.

In a method of manufacturing a semiconductor device in accordance with still another aspect of the present invention, a pad oxide layer and a hard mask layer are sequentially formed on a substrate. The hard mask layer and the pad oxide layer are patterned to form a pattern structure exposing the substrate in a first direction and including a pad oxide layer pattern and a hard mask layer pattern. Trenches that are repeatedly arranged in a first direction are formed at a surface portion of the substrate. Trench structures are formed between the trench and the pattern structure. The pattern structure is removed to expose a surface portion of the substrate between the trench structures. A tunnel oxide layer is formed on the exposed surface portion of the substrate. A first conductive layer is formed on the tunnel oxide layer. The trench structures are partially removed to form isolation layers in the trenches, a tunnel oxide layer pattern and a first conductive layer pattern. The first conductive layer pattern is patterned to form a first gate pattern on the tunnel oxide layer pattern. A dielectric layer is formed on a resultant structure having the first gate pattern. A second conductive layer is then formed on the dielectric layer. The second conductive layer is patterned to form a second gate pattern on the first gate pattern and the isolation layers. Portions of the dielectric layer exposed through the second gate pattern are patterned to form a dielectric layer pattern. The dielectric layer pattern includes a first dielectric layer pattern on the first gate pattern and the tunnel oxide layer pattern, and a second dielectric layer pattern beneath the second gate pattern.

In a method of manufacturing a semiconductor device in accordance with still another aspect of the present invention, a tunnel oxide layer, a first conductive layer and a hard mask layer are sequentially formed on a substrate. The hard mask layer, the first conductive layer and the tunnel oxide layer are patterned to form a first pattern structure exposing the substrate in a first direction and including a tunnel oxide layer pattern, a first conductive layer pattern and a hard mask layer pattern. Trenches that are repeatedly arranged in a first direction are formed at a surface portion of the substrate. The trenches are filled with isolation layers. The hard mask layer pattern is removed to form a second pattern structure including the isolation layers, the tunnel oxide layer pattern and the first conductive layer pattern. The first conductive layer pattern is patterned to form a first gate pattern on the tunnel oxide layer pattern. A dielectric layer is formed on a resultant structure having the first gate pattern. A second conductive layer is then formed on the dielectric layer. The second conductive layer is patterned to form a second gate pattern on the first gate pattern and the isolation layers. Portions of the dielectric layer exposed by or through the second gate pattern are patterned to form a dielectric layer pattern. The dielectric layer pattern includes a first dielectric layer pattern on the first gate pattern and the tunnel oxide layer pattern, and a second dielectric layer pattern beneath the second gate pattern.

According to the present invention, after the first gate pattern is formed in a land type, the dielectric layer and the second gate pattern are formed so that the dielectric layer covers an entire surface of the first gate pattern. Thus, the dielectric layer has an enlarged area so that a high coupling ratio is obtained.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, with an emphasis instead being placed upon illustrating the principles of the invention. In the drawings, the thicknesses of layers are exaggerated for clarity.

FIG. 1 is a plan view illustrating a conventional semiconductor device.

FIG. 2 is a cross-sectional view taken along line I-I′ in FIG. 1.

FIG. 3 is a cross-sectional view taken along line II-II′ in FIG. 1.

FIG. 4 is a plan view illustrating a semiconductor device in accordance with a first embodiment of the present invention.

FIG. 5 is a cross-sectional view taken along line III-III′ in FIG. 4.

FIG. 6 is a cross-sectional view taken along line IV-IV′ in FIG. 4.

FIGS. 7 to 16 are cross-sectional views illustrating a method of manufacturing the semiconductor device in FIG. 4.

FIG. 17 is a plan view corresponding to FIGS. 10 and 15.

FIGS. 18 to 27 are cross-sectional views illustrating a method of manufacturing the semiconductor device in FIG. 4 in accordance with a second embodiment of the present invention.

FIGS. 28 and 29 are plan views corresponding to FIGS. 20 and 25, respectively.

FIGS. 31 to 44 are cross-sectional views illustrating a method of manufacturing a semiconductor device in FIG. 4 in accordance with a third embodiment of the present invention.

FIGS. 45 to 54 are cross-sectional views illustrating a method of manufacturing a semiconductor device in FIG. 4 in accordance with a fourth embodiment of the present invention.

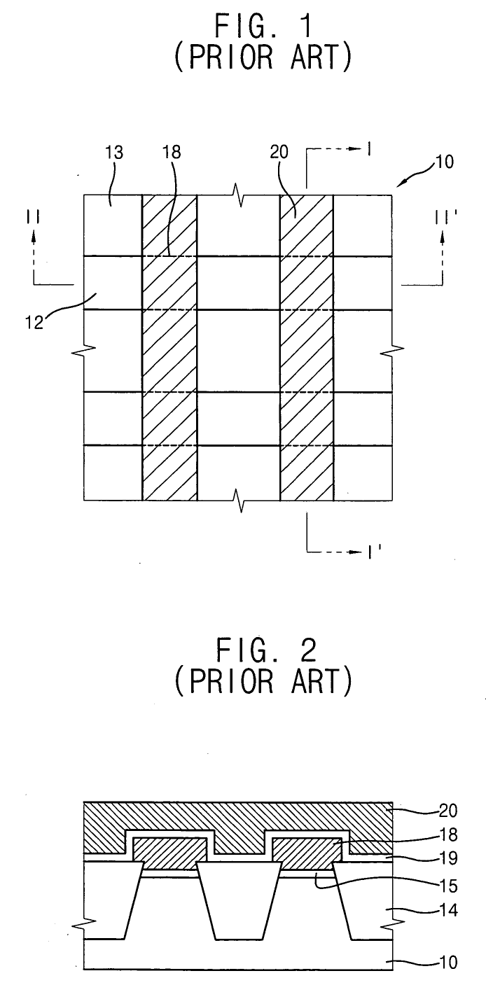

### DETAILED DESCRIPTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or a layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiment 1

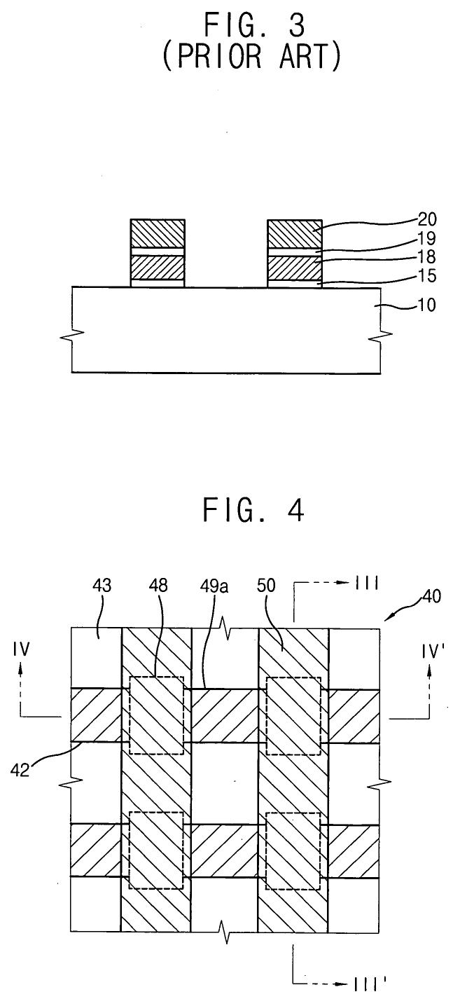

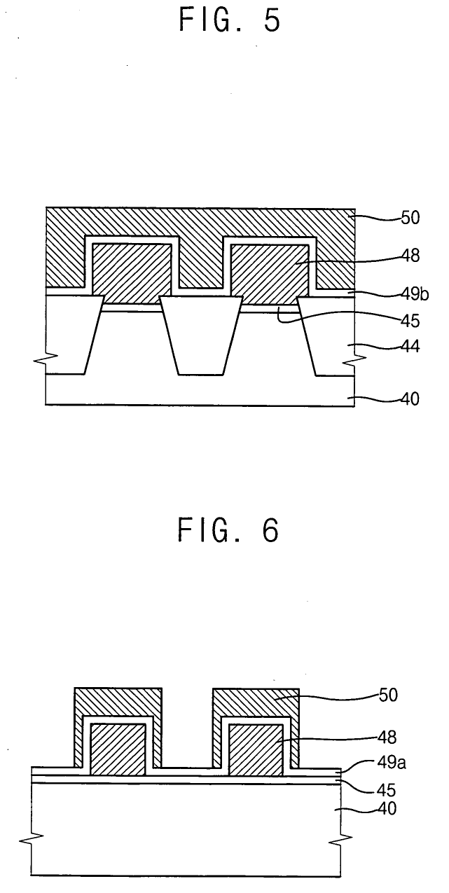

FIG. 4 is a plan view illustrating a semiconductor device in accordance with a first embodiment of the present invention. FIG. 5 is a cross-sectional view taken along line III-III′ in FIG. 4. FIG. 6 is a cross-sectional view taken along line IV-IV′ in FIG. 4. Here, line III-III′ corresponds to a second direction, line IV-IV′ corresponds to a first direction substantially perpendicular to the second direction.

Referring to FIGS. 4 to 6, a semiconductor device in accordance with present embodiment may correspond to a flash memory device. The flash memory device includes a semiconductor substrate 40, in which active regions 42 and field regions 43 are defined. The active regions 42 and the field regions 43 are alternately arranged in the first direction. In particular, as shown in FIG. 5, trenches (not shown) formed in the semiconductor substrate 40 are filled with field isolation layers 44 to define the active regions 42.

A tunnel dielectric layer pattern, e.g., a tunnel oxide layer pattern 45 is formed on the semiconductor substrate 40 in the active regions 42. A first gate pattern 48 is formed on the tunnel oxide layer pattern 45. Preferably, the first gate pattern 48 has an isolated land shape on the tunnel oxide layer pattern 45. Particularly, the first gate pattern 48 has a width in the second direction wider than that of the tunnel oxide layer pattern 45. Therefore, the first gate pattern 48 overlies a portion of the field isolation layers 44. It will be understood that the first gate pattern 48 may correspond to a floating gate of the flash memory device.

The flash memory device includes an intergate dielectric layer pattern having a first intergate dielectric layer pattern 49a and a second intergate dielectric layer pattern 49b. The first intergate dielectric layer pattern 49a extends in the first direction. In particular, as shown in FIG. 6, the first dielectric layer pattern 49a is formed on a surface of the first gate pattern 48 and a surface of the tunnel oxide layer pattern 45 exposed by or through the first gate pattern 48. The second dielectric layer pattern 49b extends in the second direction, i.e. is “striped.” The second dielectric layer pattern 49b is formed on the first gate pattern 48 and the isolation layers 44. Here, a portion of the first dielectric layer pattern 49a on the first gate pattern 48 is substantially identical to that of the second dielectric layer pattern 49b on the first gate pattern 48.

In contrast, then, to the prior art dielectric layer pattern illustrated in this direction in FIG. 3 at 19, the invented dielectric layer pattern illustrated in this same direction in FIG. 6 as the first dielectric layer pattern 49a extends down the sides of, and thus fully surrounds, the first gate pattern 48, thereby increasing the surface area of dielectric layer pattern 49a. Thus, the dielectric layer pattern may have an enlarged area compared to a conventional device. Moreover, the second gate pattern 50 in this same direction in FIG. 6 extends down the sides of, and thus also fully surrounds, the first gate pattern 48 and the surrounding dielectric layer pattern 49a, thereby increasing also the surface area of the second gate pattern 50.

A second gate pattern 50 is formed on the second dielectric layer pattern 49b and extends in the second direction. Here, since the portions of the first and second dielectric layer patterns 49a and 49b on the first gate pattern 48 are of the same structure, as shown in FIG. 6, the second gate pattern 50 is formed on the first dielectric layer pattern 49a. The second gate pattern 50 has a width in the first direction wider than that of the first gate pattern 48. Thus, the second gate pattern 50 substantially completely covers the first gate pattern. The second gate pattern 50 may correspond to a control gate of the flash memory device.

As a result, a gate structure including the tunnel oxide layer pattern 45, the first gate pattern 48, the intergate dielectric layer pattern 49a, 49b and the second gate pattern 50 are completed.

According to the flash memory device of the present embodiment, since the first and second dielectric layer patterns 49a, 49b substantially completely covers the first gate pattern 48 including four sides thereof, i.e., two sides in the first direction as well as the other two sides in the second direction, the dielectric layer pattern may have an enlarged area, thereby obtaining a high coupling ratio.

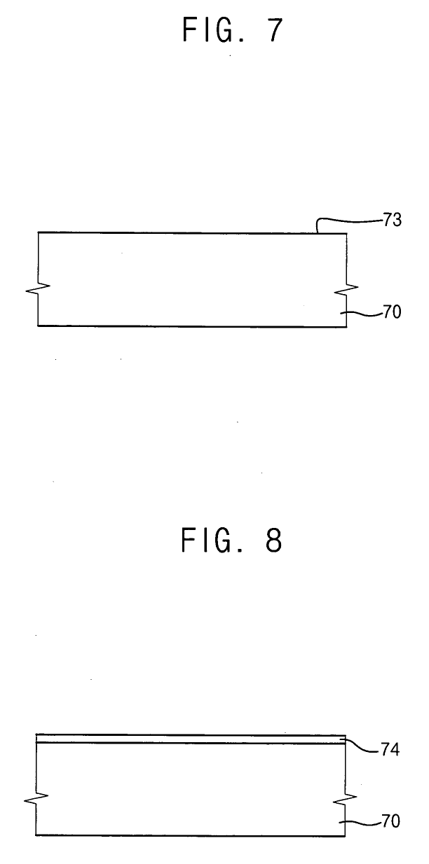

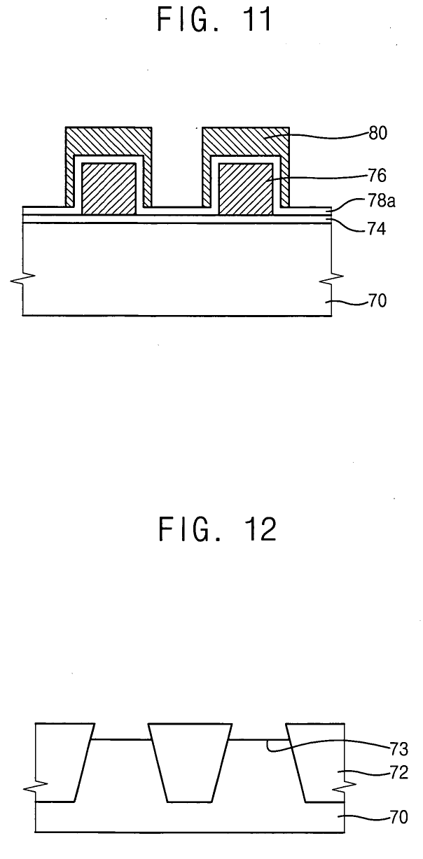

FIGS. 7 to 16 are cross-sectional views illustrating a method of manufacturing the semiconductor device in FIG. 4. FIGS. 7 to 11 are cross-sectional views taken along line IV-IV′ corresponding to the first direction and FIGS. 12 to 16 are cross-sectional views taken along line III-III′ corresponding to the second direction.

Referring to FIGS. 7 and 12, a semiconductor substrate 70 is prepared. Examples of the semiconductor substrate 70 are a silicon substrate, a silicon-on-insulator (SOI) substrate, and so on. Isolation layers 72 fill trenches formed in the semiconductor substrate 70 to form field regions such as a shallow trench isolation (STI) structure to define active regions 73 on the semiconductor substrate 70. The active regions 73 and the isolation layers 72 are alternately arranged in the first direction. An example of the isolation layers 72 is a high-density plasma chemical vapor deposition (HDP-CVD) oxide layer having a good gap-fill characteristic.

Referring to FIGS. 8 and 13, a tunnel dielectric layer, e.g., tunnel oxide layer (not shown) is formed on the semiconductor substrate 70 by a thermal oxidation process using, for example, a furnace or by a rapid thermal annealing (RTA) oxidation process. The tunnel oxide layer is patterned using a photoresist pattern (not shown) as an etching mask to form a tunnel oxide layer pattern 74 on the active regions 73.

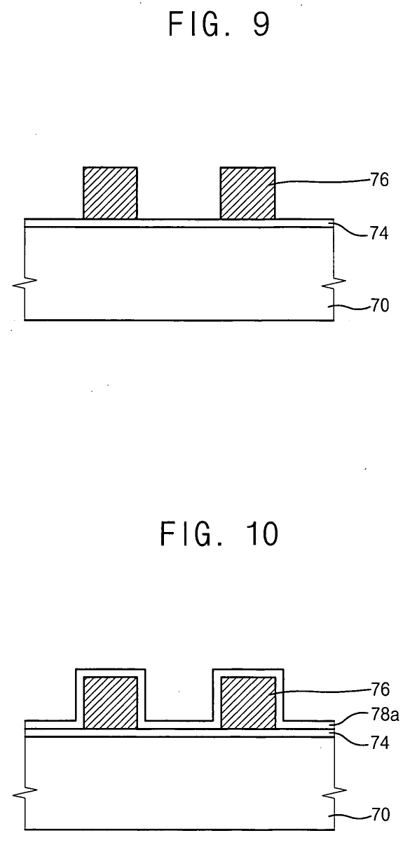

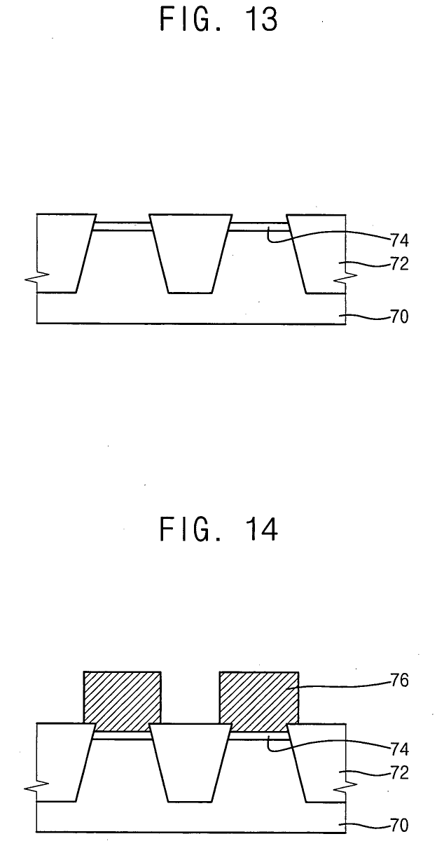

Referring to FIGS. 9 and 14, a conductive layer (not shown) is formed on the tunnel oxide layer pattern 74. Examples of the conductive layer are a polysilicon layer, a metal layer such as a tungsten layer, a metal nitride layer such as a tungsten nitride layer or a titanium nitride layer and so on. A photoresist pattern (not shown) is formed on the conductive layer in the second direction. The conductive layer is patterned using the photoresist pattern as an etching mask to form a first gate pattern 76. The first gate pattern 76 has an isolated land shape on the tunnel oxide layer pattern 74. Also, the first gate pattern 76 has a width in the second direction wider than that of the tunnel oxide layer pattern 74. The width of the first gate pattern 76 may be obtained by adjusting the width of the photoresist pattern. Thus, as shown in FIG. 14, the first gate pattern 76 is formed on a portion of the isolation layers 72.

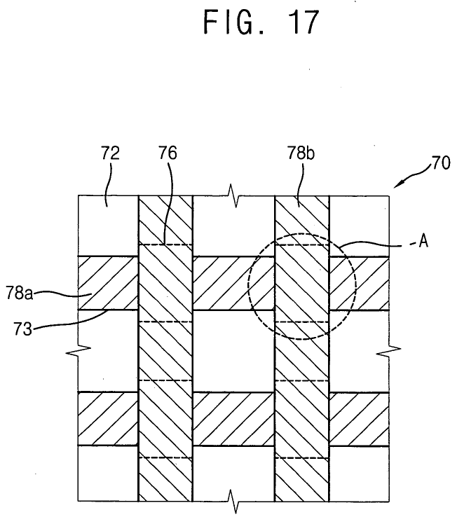

Referring to FIGS. 10 and 15, a dielectric layer is formed on first gate pattern 76, the tunnel oxide layer pattern 74 and the isolation layers 72. The dielectric layer is patterned to form an intergate dielectric layer pattern including a first dielectric layer pattern 78a and a second dielectric layer pattern 78b. The first dielectric layer pattern 78a is formed on the first gate pattern 76 and the tunnel oxide layer pattern 74. The second dielectric layer pattern 78b is formed on the first gate pattern 76 and the isolation layers 72. Particularly, with reference to FIG. 17, a portion of the first dielectric layer 78a and a portion of the second dielectric layer 78b in a region A in which the first gate pattern 76 exists correspond to the same structure.

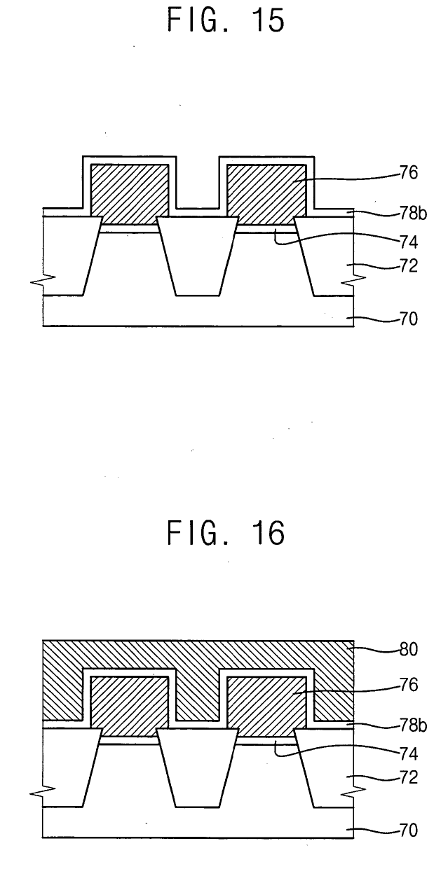

Referring to FIGS. 11 and 16, a conductive layer (not shown) is formed on the first and second dielectric layer patterns 78a and 78b. The conductive layer may include a material substantially identical to that of the first gate pattern 76 such as the polysilicon layer, the metal layer, the metal nitride layer, etc. The conductive layer is patterned to form a second gate pattern 80. The second gate pattern 80 has a width in the first direction wider than that of the first gate pattern 76. As a result, as shown in FIG. 11, the second gate pattern 80 covers the first and second dielectric layer patterns 78a and 78b.

According to the method of manufacturing the flash memory device of the present embodiment, since the first dielectric layer pattern 49a substantially completely covers the first gate pattern 48 in the first direction and the second dielectric layer pattern 49b covers the first gate pattern 48 in the second (preferably perpendicular or orthogonal) direction, the dielectric layer pattern may have an enlarged area, thereby obtaining a high coupling ratio. As a result, the flash memory device exhibits a high operation speed.

### Embodiment 2

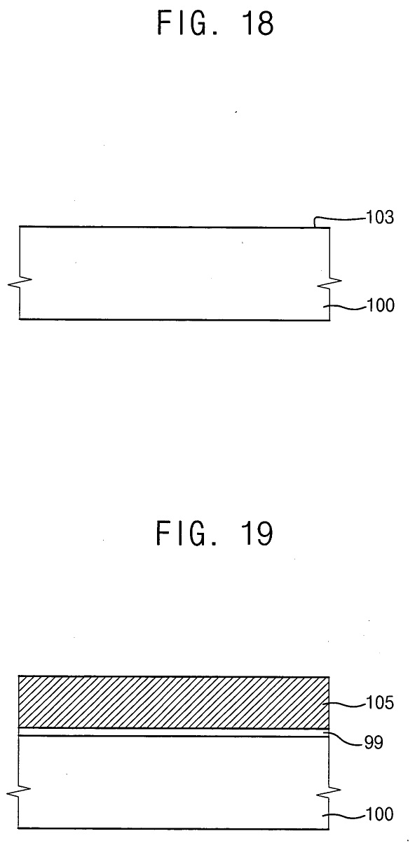

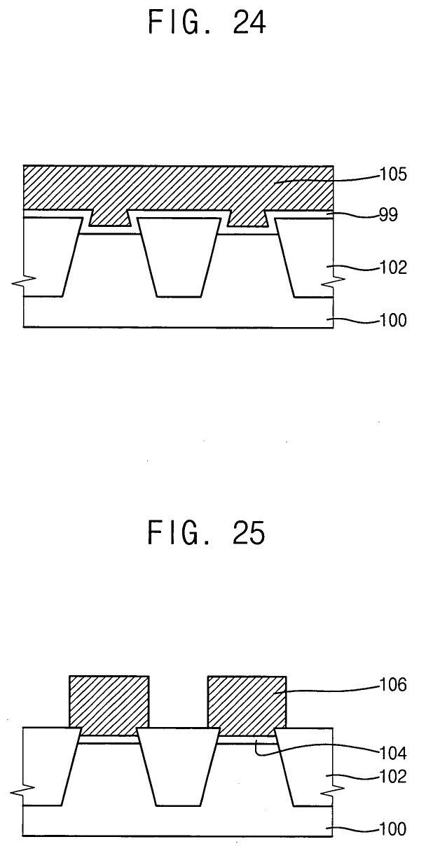

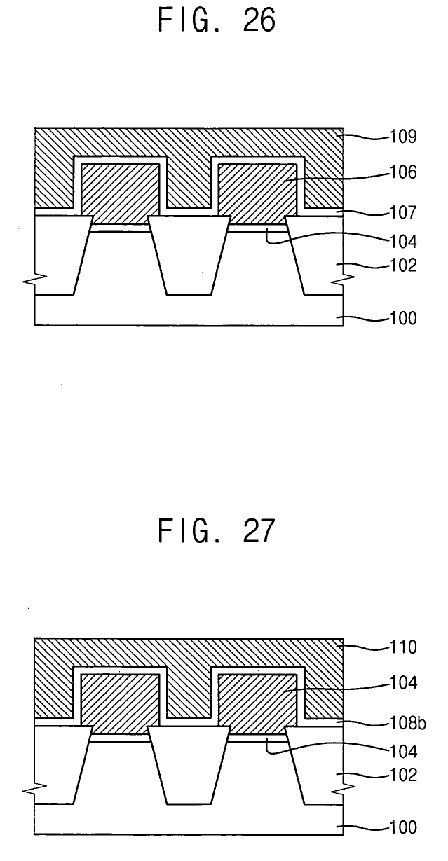

FIGS. 18 to 27 are cross-sectional views illustrating a method of manufacturing the semiconductor device in FIG. 4 in accordance with a second embodiment of the present invention. FIGS. 18 to 22 are cross-sectional views taken along line IV-IV′ corresponding to the first direction in FIG. 4 and FIGS. 23 to 27 are cross-sectional views taken along III-III′ corresponding to the second direction in FIG. 4.

Referring to FIGS. 18 and 23, a semiconductor substrate 100 is prepared. Examples of the semiconductor substrate 100 are a silicon substrate, a silicon-on-insulator (SOI) substrate and so on. Trenches of the semiconductor substrate 100 are filled with isolation layers 102 to define active regions 103 and field regions of the semiconductor substrate 100. The active regions 103 and the isolation layers 102 are alternately arranged in the first direction corresponding to line IV-IV′. An example of the isolation layers 102 is an HDP-CVD oxide layer having a good gap-fill characteristic.

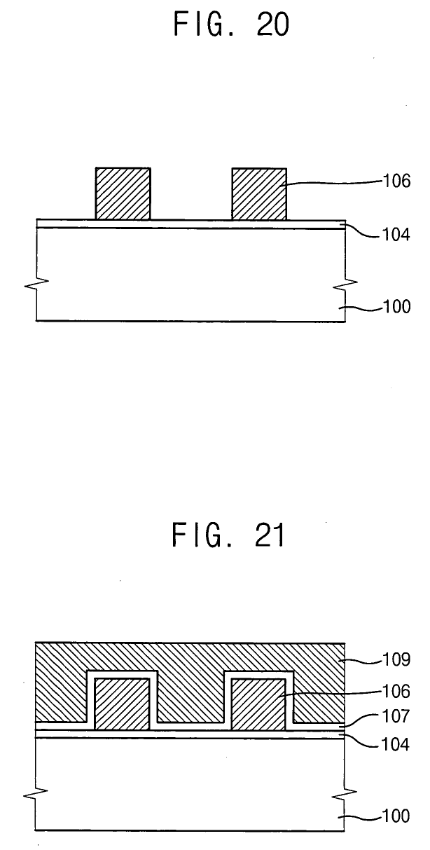

Referring to FIGS. 19 and 24, a tunnel dielectric layer such as a tunnel oxide layer 99 comprising silicon oxide is formed on the semiconductor substrate 100 by a thermal oxidation process or an RTP oxidation process. The tunnel oxide layer 99 has a thickness of about 10 Å to about 500 Å, preferably about 50 Å to about 300 Å, more preferably about 50 Å to about 200 Å. In the present embodiment, the tunnel oxide layer 99 has a thickness of about 100 Å.

A first conductive layer 105 is formed on the tunnel oxide layer 99. Examples of the first conductive layer 105 are a polysilicon layer, a metal layer, a metal nitride layer, etc. The first conductive layer 105 has a thickness of about 700 Å to about 1,500 Å, preferably about 300 Å to about 1,200 Å, more preferably about 1,000 Å. In particular, the first conductive layer 105 is not formed at a contact region. Thus, any required consideration of a gap-fill margin of the first conductive layer 105 is obviated. As a result, the first conductive layer 105 includes a dense structure without voids.

In particular, the first conductive layer 105 including a first polysilicon is formed by a first process for forming the first conductive layer 105 and a second process for doping the first conductive layer 105 with impurities. The first process may be performed in a furnace at a temperature of about 500° C. to about 650° C. under a pressure of about 25 Pascal (Pa) to about 150 Pa using about 100% by weight of a silane gas or about 20% to about 30% by weight of a silane gas diluted by a diluting gas such as a nitrogen gas. After the first process is completed, the impurities are implanted into the first conductive layer 105 at a relatively low temperature. Alternatively, the second process can include a diffusion process or an in situ doping process. According to the in situ doping process, an impurity gas is introduced into the furnace in performing the first process. Optionally, a plasma doping process can be used for doping the first conductive layer 105.

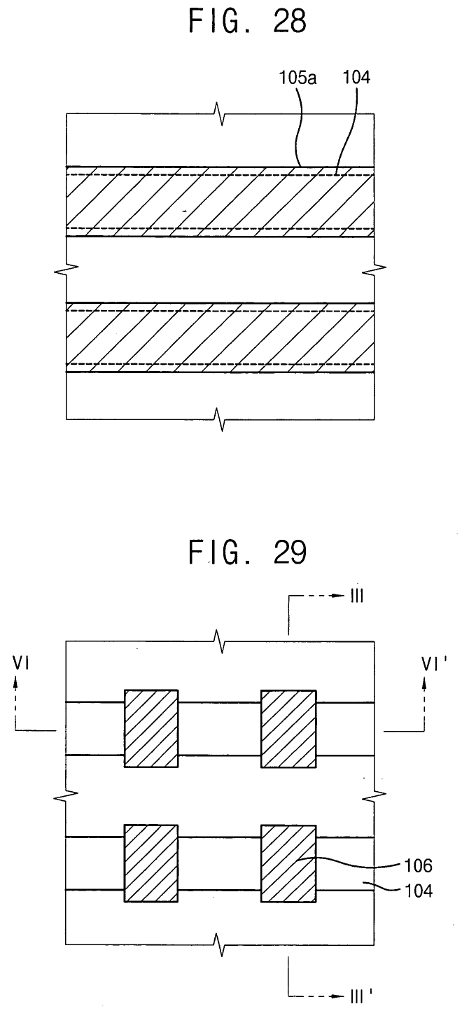

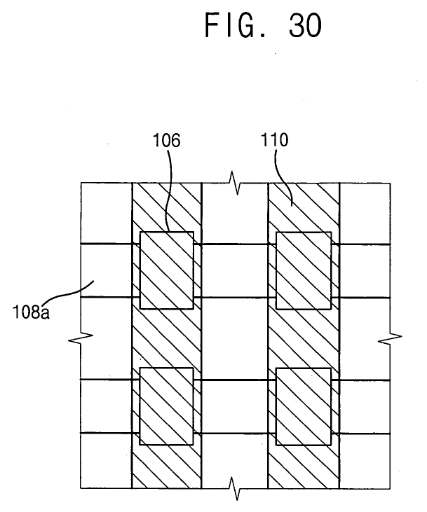

Referring to FIGS. 20, 25, 28 and 29, portions of the first conductive layer 105 and the tunnel oxide layer 99 on the isolation layers 102 are partially removed to form a tunnel oxide layer pattern 104 and a first conductive layer pattern 105a. Here, the first conductive layer pattern 105a has a width in the second direction wider than that of the tunnel oxide layer pattern 104. The first conductive layer pattern 105a is patterned to form a first gate pattern 106 having an isolated land shape on the tunnel oxide layer pattern 104.

Referring to FIGS. 21 and 26, a dielectric layer 107 is formed on the first gate pattern 106 and the tunnel oxide layer pattern 104. Examples of the dielectric layer 107 are an oxide-nitride-oxide (ONO) layer, a high-k dielectric such as high-k metal oxide layer and so on. Examples of the metal oxide layer are a hafnium oxide layer, a titanium oxide layer and so on. The metal oxide layer can be formed by an atomic layer deposition (ALD) process. A second conductive layer 109 is formed on the dielectric layer 107. The second conductive layer 109 is formed by a process substantially identical to that for forming the first conductive layer 105 except for the thickness. That is, the second conductive layer 109 has a thickness different from that of the first conductive layer 105.

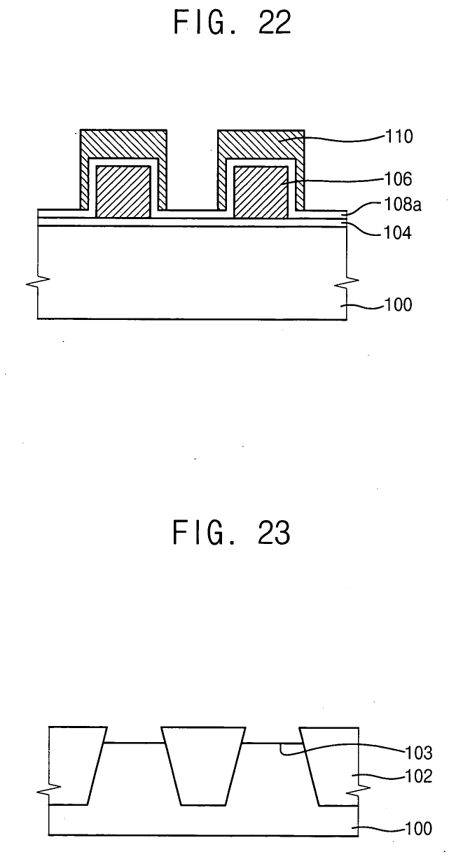

Referring to FIGS. 22, 27 and 30, the second conductive layer 109 is patterned to form a second gate pattern 110 over the first gate pattern 106 and the isolation layers 102. Here, the second gate pattern 110 has a width in the first direction wider than that of the first gate pattern 106 so that the second gate pattern 110 covers the first gate pattern 106.

The dielectric layer 107 exposed by or through the second gate pattern 110 is patterned to form an intergate dielectric layer pattern including a first dielectric layer pattern 108a and a second dielectric layer pattern 108b. The first dielectric layer pattern 108a is positioned on the first gate pattern 106 and on the tunnel oxide layer pattern 104. The first dielectric layer pattern 108a covers the first gate pattern 106. The second dielectric layer pattern 108b corresponds to a portion of the dielectric layer 107 beneath the second gate pattern 110.

According to the method of manufacturing the semiconductor device of the present embodiment, since the dielectric layer pattern has an enlarged area, a high coupling ratio is obtained. Also, the first gate pattern 106 corresponds to a floating gate of the flash memory device and the second gate pattern 110 corresponds to a control gate of the flash memory device. Thus, the flash memory device exhibits a high operation speed.

### Embodiment 3

FIGS. 31 to 44 are cross-sectional views illustrating a method of manufacturing a semiconductor device in FIG. 4 in accordance with a third embodiment of the present invention. FIGS. 31 to 37 are cross-sectional views taken along line IV-IV′ corresponding to the first direction in FIG. 4 and FIGS. 38 to 44 are cross-sectional views taken along line III-III′ corresponding to the second direction in FIG. 4.

Referring to FIGS. 31 and 38, a pad oxide layer (not shown) is formed on a semiconductor substrate 130. A hard mask layer (not shown) including nitride is formed on the pad oxide layer. The hard mask layer and the pad oxide layer are patterned in the first direction corresponding to line IV-IV′ until the semiconductor substrate 130 is exposed to form pattern structures 135 including a pad oxide layer pattern 132 and a hard mask layer pattern 134.

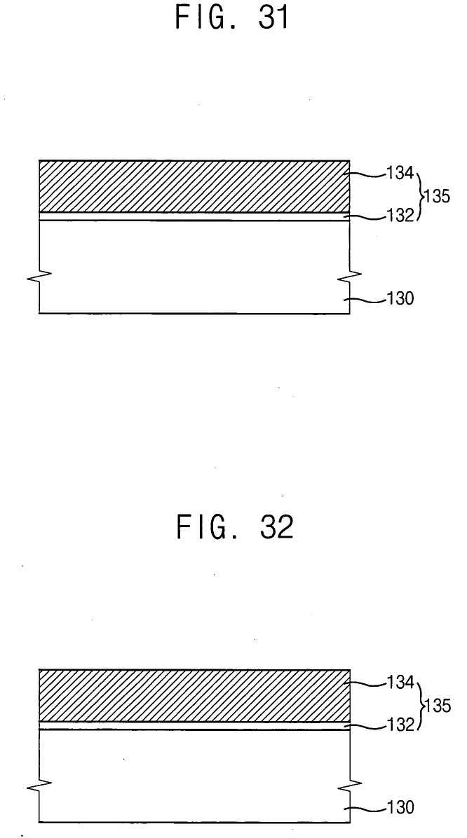

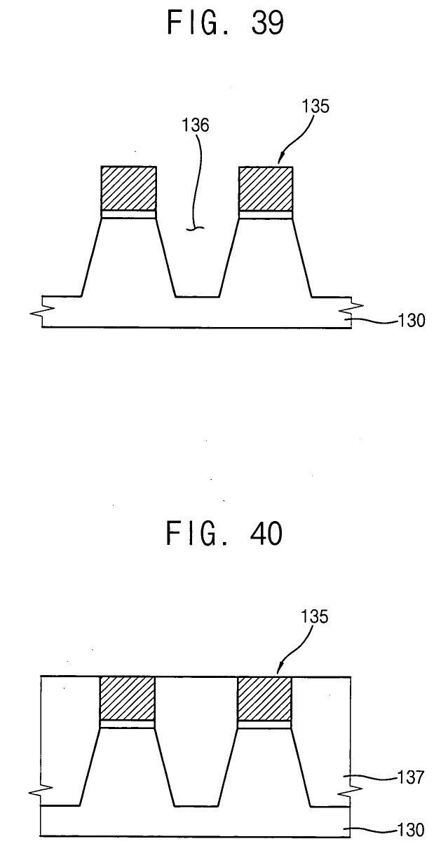

Referring to FIGS. 32 and 39, the semiconductor substrate 130 is partially etched using the pattern structure 135 as an etching mask to form a trench 136. Additionally, to cure damage of a side face of the trench 136, an oxide layer (not shown) can be formed on the side surface of the trench 136.

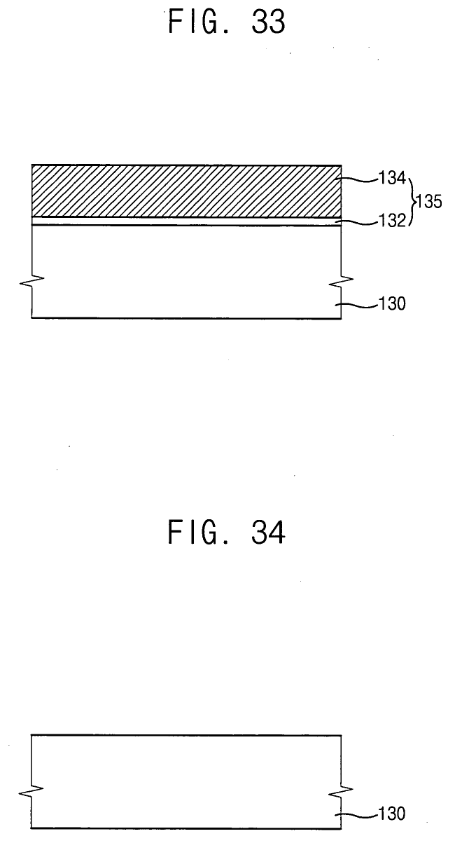

Referring to FIGS. 33 and 40, the trench 136 and a space between the pattern structures 135 are filled with a trench isolation structure 137. An example of the trench isolation structure 137 is a HDP-CVD gap-fill layer such as a silicon dioxide layer. It may be seen that, to form the trench isolation structure 137, an insulation layer (not shown) is formed in the trench 136, the space between the pattern structures 135 and on the pattern structures 135. The insulation layer may then be planarized by a conventional planarizing process such as a CMP process until the pattern structures 135 are exposed to form the trench structure 137.

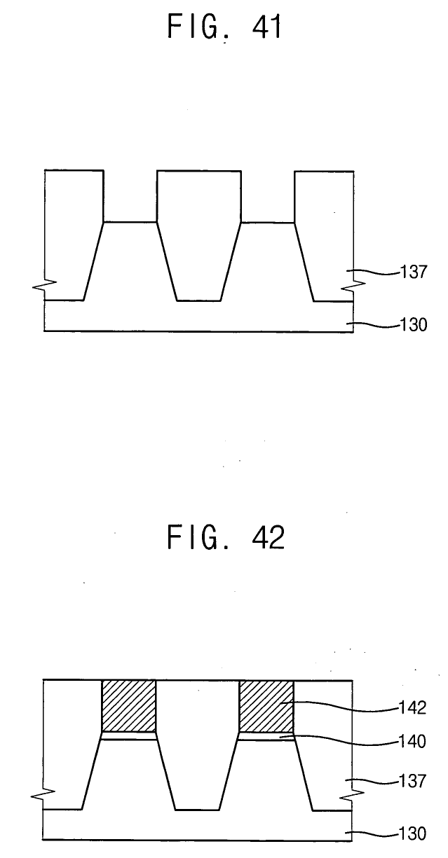

Referring to FIGS. 33 and 41, the pattern structures 135 are removed to expose the semiconductor substrate 130 between the trench structures 137.

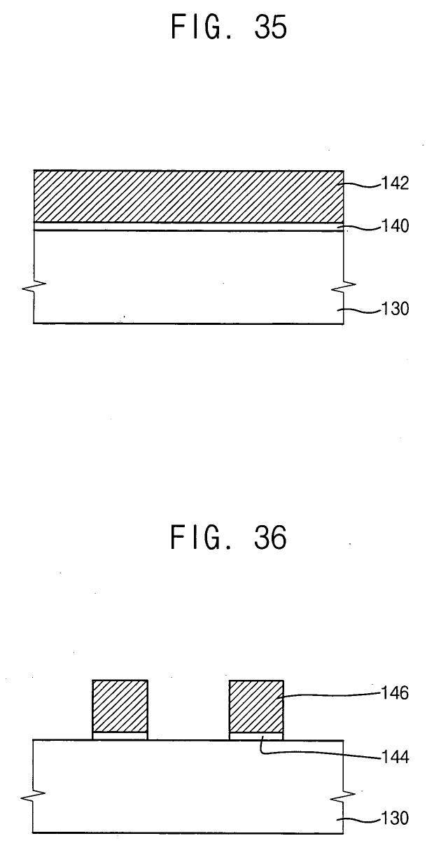

Referring to FIGS. 35 and 42, a tunnel dielectric layer such as a tunnel oxide layer 140 is formed on the semiconductor substrate 130 between the trench structures 137. The tunnel oxide layer 140 is formed by a process substantially identical to that for forming the tunnel oxide layer in Embodiment 2. A first conductive layer 142 is formed on the resulting structure including the tunnel oxide layer 140 to fill the space with the first conductive layer 142. The first conductive layer 142 is formed by a process substantially identical to that for forming the first conductive layer in Embodiment 2. Because the space is sufficiently filled with the first conductive layer 142, the thickness of the first conductive layer 142 in accordance with a gap-filling margin may be considered. Thus, the first conductive layer 142 has a thickness of about 700 Å to about 1,500 Å.

According to one aspect of the present invention, to form the first conductive layer 142, a conductive layer (not shown) is formed on the tunnel oxide layer 140. The conductive layer is planarized by a CMP process until the trench structures 137 are exposed to form the first conductive layer 142.

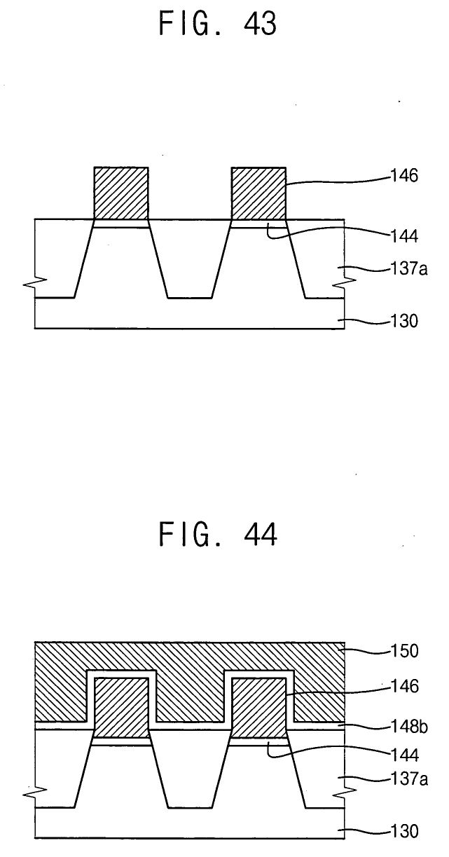

Referring to FIGS. 36 and 43, the trench structures 137 are partially removed to form isolation layers 137a in the trenches 136 and a tunnel oxide layer pattern 144 and a first conductive layer pattern 146 on the semiconductor substrate 130. The first conductive layer pattern 146 corresponds to a first gate pattern. Because the isolation layers 137a are arranged in the first direction, the tunnel oxide layer pattern 144 and the first conductive layer pattern 146 also are arranged in the first direction. Thus, the first gate pattern 146 is positioned on the tunnel oxide layer pattern 144.

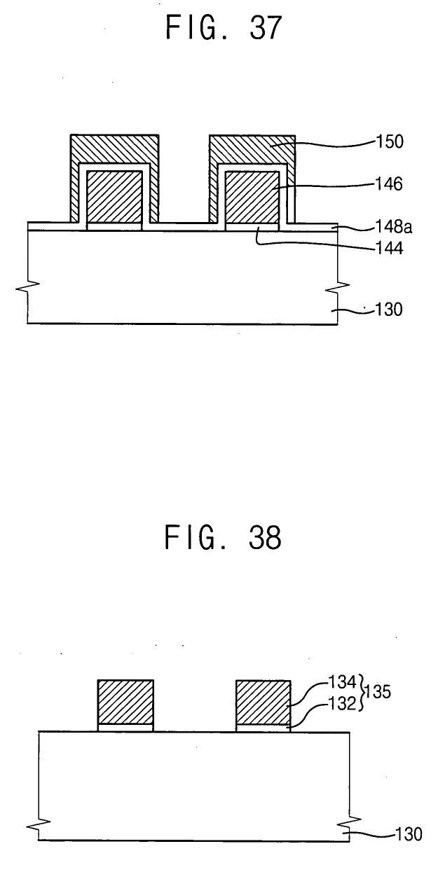

Referring to FIGS. 37 and 44, an intergate dielectric layer pattern including a first dielectric layer pattern 148a and a second dielectric layer pattern 148b is formed on the first gate pattern 146, a side face of the tunnel oxide layer pattern 144 and on the isolation layers 137a by a process substantially identical to that for forming the dielectric layer pattern in Embodiment 2.

According to the method of manufacturing the semiconductor device of the present embodiment, since the dielectric layer pattern has an enlarged area, a high coupling ratio is obtained. Also, the first gate pattern corresponds to a floating gate of the flash memory device and the second gate pattern corresponds to a control gate of the flash memory device. Thus, the flash memory device exhibits a high operation speed.

### Embodiment 4

FIGS. 45 to 54 are cross-sectional views illustrating a method of manufacturing a semiconductor device in FIG. 4 in accordance with a fourth embodiment of the present invention. FIGS. 45 to 49 are cross-sectional views taken along line IV-IV′ in FIG. 4 and FIGS. 50 to 54 are cross-sectional views taken along line III-III′ in FIG. 4.

Referring to FIGS. 45 and 50, a tunnel dielectric layer, e.g., a tunnel oxide layer (not shown) is formed on a semiconductor substrate 170. A first conductive layer (not shown) is formed on the tunnel oxide layer. The tunnel oxide layer and the first conductive layer are formed by processes substantially identical to those for forming the tunnel oxide layer and the first conductive layer in Embodiment 2. A hard mask layer (not shown) including a suitable material such as nitride is formed on the first conductive layer by a process substantially identical to that for forming the hard mask layer in Embodiment 3. The hard mask layer, the first conductive layer and the tunnel oxide layer are patterned until the semiconductor substrate 170 is exposed to form first pattern structures 177 including a tunnel oxide layer pattern 172, a first conductive layer pattern 174 and a hard mask layer pattern 176. It may be seen that the first pattern structures 177 are repeatedly arranged in the first direction corresponding to line IV-IV′. Also, the tunnel oxide layer pattern 172 has a thickness of about 10 Å to about 500 Å. The first conductive layer pattern 174 has a thickness of about 700 Å to about 1,550 Å.

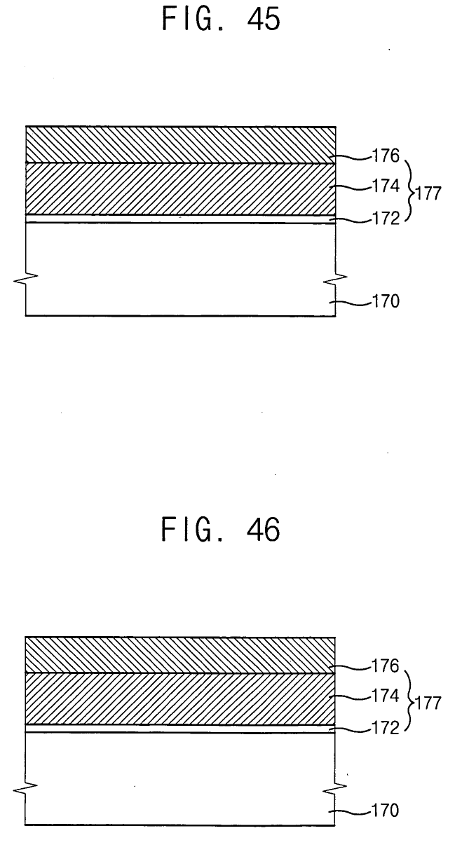

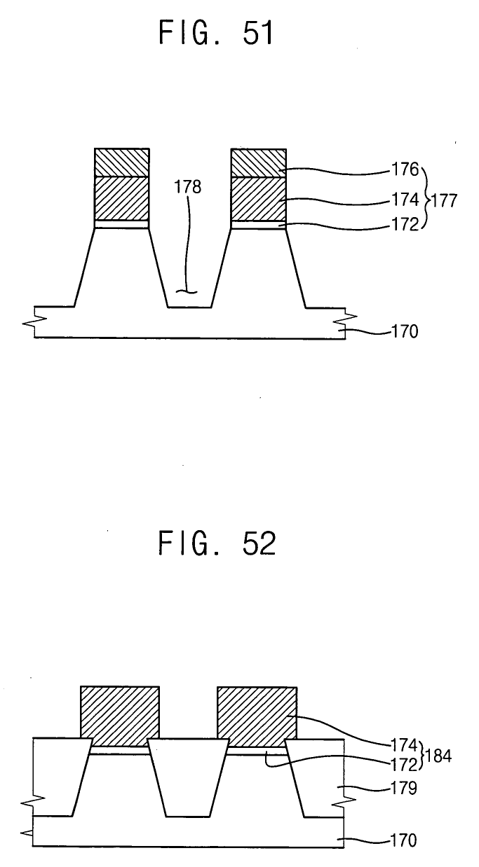

Referring to FIGS. 46 and 51, the semiconductor substrate 170 is partially etched using the first pattern structures 177 as an etching mask to form trenches 178.

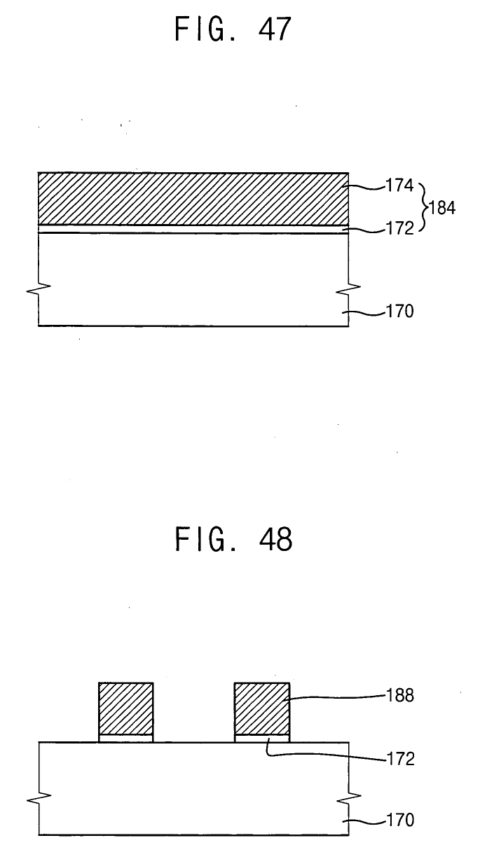

Referring to FIGS. 47 and 52, the trenches 178 are filled with isolation layers 179 including an insulation material. An example of the isolation layers 179 is a high-density plasma oxide layer. To form the isolation layers 179, an insulation layer (not shown) is formed in the trenches 178, a space between the first pattern structures 177 and on the first pattern structures 177. The insulation layer is planarized by a CMP process until the first pattern structures 177 are exposed to form the isolation layers 179. The hard mask layer pattern 176 is partially removed to form second pattern structures 184 including the tunnel oxide layer pattern 172 and the first conductive layer pattern 174. In particular, the isolation layers 179 and the second pattern structures 184 are alternately arranged in the first direction. Also, the second pattern structures 184 have a width in a second direction substantially perpendicular to the first direction that is wider than that of the tunnel oxide layer pattern 172.

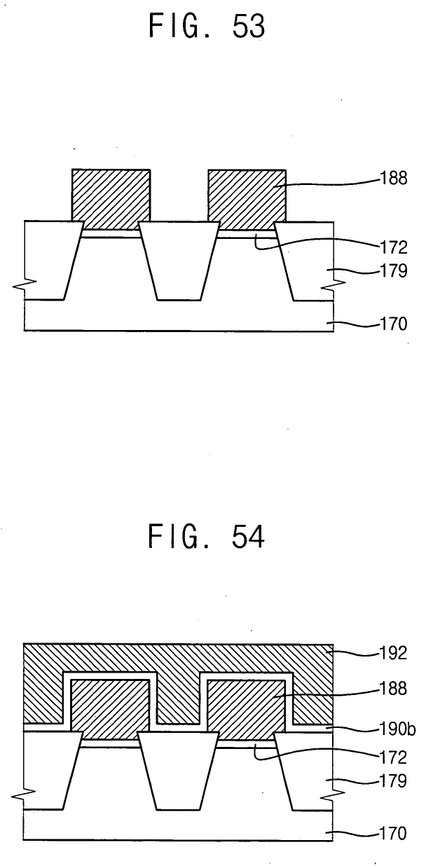

Referring to FIGS. 48 and 53, the first conductive layer pattern 174 is patterned to form a first gate pattern 188 having a land shape on the tunnel oxide layer pattern 172.

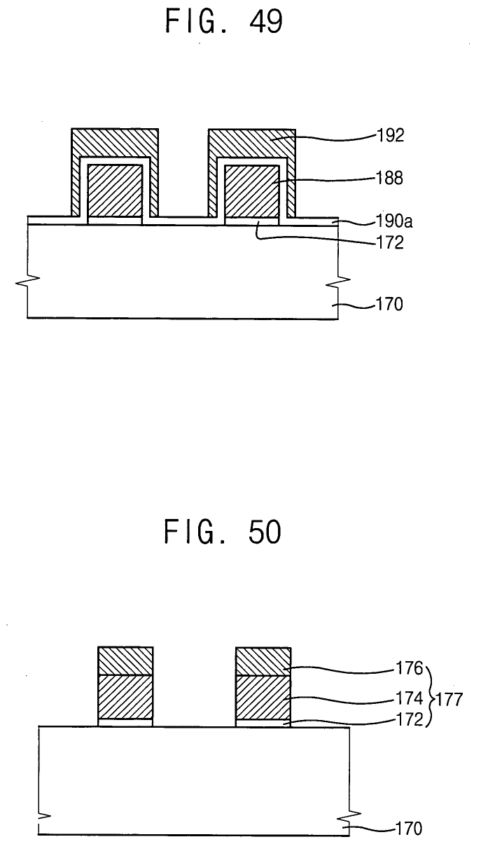

Referring to FIGS. 49 and 54, an intergate dielectric layer pattern including a first dielectric layer pattern 190a and a second dielectric layer pattern 190b is formed on the first gate pattern 188, a side face of the tunnel oxide layer pattern 172 and on the isolation layers 179 by a process substantially identical to that for forming the dielectric layer pattern in Embodiment 2. The first dielectric layer pattern 190a extends down to sides of the first gate pattern 188, with the sides extending along the second direction.

According to the method of manufacturing the semiconductor device of the present embodiment, since the dielectric layer pattern has an enlarged area, a high coupling ratio is obtained. Also, the first gate pattern corresponds to a floating gate of the flash memory device and the second gate pattern corresponds to a control gate of the flash memory device. Thus, the flash memory device exhibits a high operation speed.

According to an aspect of the present invention, after the first gate pattern corresponding to the floating gate is formed, the intergate dielectric layer pattern is formed. Thus, the dielectric layer pattern covers the first gate pattern so that the area of the dielectric layer pattern is increased. As a result, a high coupling ratio is readily obtained so that the semiconductor device exhibits a high operation speed.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A semiconductor device comprising:
a substrate having active regions and field regions that are alternately arranged in a first direction;
a tunnel dielectric layer pattern formed on the active regions;
a first gate pattern partially formed on the tunnel dielectric layer pattern;
an intergate dielectric layer pattern including a first dielectric layer pattern overlying the first gate pattern and the tunnel dielectric layer pattern exposed by the first gate pattern, and a second dielectric layer pattern overlying the first gate pattern and the field regions, the second dielectric layer pattern extending in a second direction substantially perpendicular to the first direction; and
a second gate pattern formed on the second dielectric layer pattern.

2. The semiconductor device of claim 1, wherein the field regions are defined by isolation layers with which trenches of the substrate are filled.

3. The semiconductor device of claim 1, wherein the first gate pattern has a width in the second direction wider than that of the tunnel dielectric layer pattern.

4. The semiconductor device of claim 1, wherein the second dielectric layer pattern has substantially the uniform width in the second direction.

5. The semiconductor device of claim 1, wherein the second gate pattern has a width in the first direction wider than that of the first gate pattern.

6. A method of manufacturing a semiconductor device, the method comprising:
defining active regions and field regions of a substrate that are alternately arranged in a first direction;
forming a tunnel dielectric layer pattern on the active regions;
partially forming a first gate pattern on the tunnel dielectric layer pattern;
forming an intergate dielectric layer pattern that includes a first dielectric layer pattern and a second dielectric layer pattern, the first dielectric layer pattern overlying the first gate pattern and the tunnel dielectric layer pattern exposed by the first gate pattern, and the second dielectric layer pattern overlying the first gate pattern and the field regions and extending in a second direction substantially perpendicular to the first direction; and
forming a second gate pattern on the second dielectric layer pattern.

7. The method of claim 6, wherein the field regions are defined by isolation layers with which trenches of the substrate are filled.

8. The method of claim 6, wherein the first gate pattern has a width in the second direction wider than that of the tunnel dielectric layer pattern.

9. The method of claim 6, wherein the second dielectric layer pattern has substantially the uniform width in the second direction.

10. The method of claim 6, wherein the second gate pattern has a width in the first direction wider than that of the first gate pattern.

11. A method of manufacturing a semiconductor device, the method comprising:
filling trenches of a substrate with isolation layers to define active regions and field regions that are alternately arranged in a first direction;
sequentially forming a tunnel dielectric layer and a first conductive layer on the substrate;
patterning the first conductive layer and the tunnel dielectric layer to form a tunnel dielectric layer pattern on the active regions and a first conductive layer pattern on the tunnel dielectric layer pattern;
patterning the first conductive layer pattern to form a first gate pattern on the tunnel dielectric layer pattern;
forming an insulating layer on the first gate pattern, the tunnel dielectric layer pattern and the isolation layers;
forming a second conductive layer on the insulating layer;
patterning the second conductive layer to form a second gate pattern on the first gate pattern and the isolation layers, the second gate pattern extending in a second direction substantially perpendicular to the first direction; and
patterning the insulating layer to form an intergate dielectric layer pattern including a first dielectric layer pattern and a second dielectric layer pattern, the first dielectric layer pattern being formed on the first gate pattern and on the tunnel dielectric layer pattern exposed by the first gate pattern, and the second dielectric layer pattern being formed beneath the second gate pattern.

12. The method of claim 11, wherein the tunnel dielectric layer pattern has a thickness of about 10 Å to about 500 Å.

13. The method of claim 11, wherein the first conductive layer pattern has a thickness of about 700 Å to about 1,500 Å.

14. The method of claim 11, wherein the first and second conductive layers comprise a polysilicon layer.

15. The method of claim 11, wherein the dielectric layer comprises an oxide-nitride-oxide (ONO) layer or a metal oxide layer.

16. The method of claim 11, wherein the second gate pattern has a width in the first direction wider than that of the first gate pattern.

17. A method of manufacturing a semiconductor device, the method comprising:
sequentially forming a pad oxide layer and a hard mask layer on a substrate;
patterning the hard mask layer and the pad oxide layer until the substrate is exposed to form pattern structures including a pad oxide layer pattern and a hard mask layer pattern;
forming trenches in the substrate;
forming trench structures in the trenches and a space between the pattern structures;
removing the pattern structures to partially expose the substrate;
forming a tunnel dielectric layer on the substrate;
forming a first conductive layer on the tunnel dielectric layer;
patterning the trench structures to form isolation layers repeatedly arranged in a first direction in the trenches, and a tunnel dielectric layer pattern and a first conductive layer pattern on the substrate;
patterning the first conductive layer pattern to form a first gate pattern on the tunnel dielectric layer pattern;
forming an insulating layer on the first gate pattern, the tunnel dielectric layer pattern and the isolation layers;
forming a second conductive layer on the insulating layer;
patterning the second conductive layer to form a second gate pattern on the first gate pattern and the isolation layers, the second gate pattern extending in a second direction substantially perpendicular to the first direction; and
patterning the insulating layer to form an intergate dielectric layer pattern including a first dielectric layer pattern and a second dielectric layer pattern, the first dielectric layer pattern being formed on the first gate pattern and on the tunnel dielectric layer pattern exposed through the first gate pattern, and the second dielectric layer pattern being formed beneath the second gate pattern.

18. The method of claim 17, wherein forming the trench structures comprise:
filling the trenches and the space between the pattern structures with an insulation layer; and
planarizing the insulation layer until the pattern structures are exposed to form the trench structures.

19. The method of claim 17, wherein forming the first conductive layer comprises:
forming a preliminary conductive layer on the tunnel oxide layer; and
planarizing the preliminary conductive layer until the trench structures are exposed to form the first conductive layer.

20. The method of claim 17, wherein the tunnel oxide layer pattern has a thickness of about 10 Å to about 500 Å and the first conductive layer pattern has a thickness of about 700 Å to about 1,500 Å.

21. The method of claim 17, wherein the first and second conductive layers comprise a polysilicon layer.

22. The method of claim 17, wherein the dielectric layer comprises an oxide-nitride-oxide (ONO) layer or a metal oxide layer.

23. The method of claim 17, wherein the second gate pattern has a width in the first direction wider than that of the first gate pattern.

24. A method of manufacturing a semiconductor device, the method comprising:
sequentially forming a tunnel dielectric layer, a first conductive layer and a hard mask layer on a substrate;
patterning the hard mask layer, the first conductive layer and the tunnel dielectric layer until the substrate is exposed to form first pattern structures including a tunnel dielectric layer pattern, a first conductive layer pattern and a hard mask layer pattern;
forming trenches at a surface portion of the substrate;
filling the trenches and a space between the first pattern structures with isolation layers;
removing the hard mask layer pattern to form second pattern structures including the isolation layers repeatedly arranged in a first direction, the tunnel dielectric layer pattern and the first conductive layer pattern;
patterning the first conductive layer pattern to form a first gate pattern on the tunnel dielectric layer pattern;
forming a dielectric layer on the first gate pattern, the tunnel dielectric layer pattern and the isolation layers;
forming a second conductive layer on the dielectric layer;
patterning the second conductive layer to form a second gate pattern on the first gate pattern and the isolation layers, the second gate pattern extending in a second direction substantially perpendicular to the first direction; and
patterning the dielectric layer to form a dielectric layer pattern including a first dielectric layer pattern and a second dielectric layer pattern, the first dielectric layer pattern being formed on the first gate pattern and on the tunnel dielectric layer pattern exposed through the first gate pattern, and the second dielectric layer pattern being formed beneath the second gate pattern.

25. The method of claim 24, wherein forming the isolation layers comprise:
filling the trenches and the space between the first pattern structures with an insulation layer;
planarizing the insulation layer to expose the first pattern structures; and
partially removing the insulation layer to form the isolation layers.

26. The method of claim 24, wherein the tunnel dielectric layer pattern has a thickness of about 10 Å to about 500 Å and the first conductive layer pattern has a thickness of about 700 Å to about 1,500 Å.

27. The method of claim 24, wherein the first and second conductive layers comprise a polysilicon layer.

28. The method of claim 24, wherein the dielectric layer comprises an oxide-nitride-oxide (ONO) layer or a metal oxide layer.

29. The method of claim 24, wherein the second gate pattern has a width in the first direction wider than that of the first gate pattern.
